(19) United States
(12) Patent Application Publication
(10) Pub. No.: US 2006/0090702 A1
(43) Pub. Date: May 4, 2006

(54) Duplex chemical vapor deposition system and pulsed processing method using the same

(75) Inventors: June-mo Koo, Seoul (KR); Young-soo Park, Gyeonggi-do (KR); Sang-min Shin, Seoul (KR); Suk-pil Kim, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Gyeonggi-do (KR)

(21) Appl. No.: 11/185,689

(22) Filed: Jul. 21, 2005

(30) Foreign Application Priority Data
Oct. 28, 2004 (KR) 10-2004-0086540

(51) Int. Cl. C23C 16/00

(52) U.S. Cl. 118/719; 427/248.1; 118/715

(57) ABSTRACT

Embodiments are provided of a duplex chemical vapor deposition (CVD) system and pulsed processing method using the same. The duplex CVD system may include first and second process chambers, one or more reactive sources, and reactive source suppliers that correspond to the reactive sources, respectively. The reactive source suppliers may include a first conduit portion connected to the respective reactive sources, a second conduit portion having one terminal connected to the first conduit portion and the other terminal connected to the first process chamber, and a third conduit portion having one terminal connected to the first conduit portion and the other terminal connected to the second process chamber.

### CROSS-REFERENCE TO RELATED PATENT APPLICATION

This application claims the benefit of Korean Patent Application No. 10-2004-0086540, filed on Oct. 28, 2004, in the Korean Intellectual Property Office, the disclosure of which is incorporated herein in its entirety by reference.

### BACKGROUND OF THE DISCLOSURE

1. Field of the Disclosure

The present invention relates to an apparatus for fabricating semiconductor devices, more particularly, to a duplex chemical vapor deposition (CVD) system and a pulsed processing method using the same.

2. Description of the Related Art

In recent years, with the expansion of markets for mobile phones or digital cameras, the demand for nonvolatile memory devices has increased because the nonvolatile memory devices can retain stored data even if power supply is abruptly interrupted unlike conventional DRAMs. In this connection, a ferroelectric RAM (FRAM) has lately attracted much attention as one of the nonvolatile memory devices. This FRAM operates based on the spontaneous polarization of a ferroelectric material. Even if an external electric field is removed, a large portion of polarization still remains in the ferroelectric material. Also, a direction of the spontaneous polarization can be shifted by changing a direction of the external electric field.

Typical examples of the ferroelectric material are PZT(Pb(Zr, Ti)O₃) and SBT(SrBi₂Ta₂O₉). These ferroelectric materials may be deposited using a variety of methods. Among them, a chemical vapor deposition (CVD) method (esp., a metal organic CVD (MOCVD) method using an organic source) is being widely used. Hereinafter, a conventional CVD system will be described with reference to FIG. 1.

FIG. 1 is a construction diagram of a process chamber unit 100 of the conventional CVD system. Here, reactive sources are exemplarily presented to form a PZT layer, which is one of ferroelectric layers.

Referring to FIG. 1, the process chamber unit 100 includes a process chamber 101 and additional suppliers of liquid and gas sources 102, 104, 106, 108, 122, 124, and 126, which are attached to the process chamber 101. Typically, the conventional CVD system is comprised of a plurality of process chamber units 100 for the purpose of mass production. However, since the respective process chamber units 100 are almost the same, only one of them will be exemplarily described now.

As shown in FIG. 1, in the process chamber unit 100, respective liquid mass flow controllers (LMFCs) 112, 114, and 116 control the flow rates of the Pb, Zr, and Ti liquid sources 102, 104, and 106 injected into the process chamber 101 except a solvent 108. Also, when the liquid sources 102, 104, and 106 are injected into the process chamber 101 at once, they are mixed by a mixer 154 beforehand.

The mixed liquid sources 102, 104, and 106 are evaporated by an evaporator 156 and injected into the process chamber 101. In this case, a carrier gas is used to facilitate the evaporation and injection of the mixed liquid sources 102, 104, and 106. As shown in FIG. 1, an inert gas, such as Ar gas 124, is widely used as the carrier gas. The flow rate of the Ar gas 124 is controlled by a gas mass flow controller (MFC) 134.

As shown in FIG. 1, the mixed liquid sources 102, 104, and 106 are carried through a first conduit portion 151 to a second conduit portion 141 in which the Ar gas 124 is injected. In an initial operation of a process, the liquid sources 102, 104, and 106 are exhausted through an additional purge conduit portion 147 for process stability. In this case, respective valves 151a, 141a, and 147a allow the first and second conduit portions 151 and 141 and the purge conduit portion 147 to open or close off.

Meanwhile, the solvent 108 is controlled by an LMFC 118 and carried through a third conduit portion 149 to the second conduit portion 141. In this case, an additional valve 149a allows the third conduit portion 149 to open or close off.

In addition to the liquid sources 102, 104, 106, and 108, gas sources may be injected into the process chamber 101. For example, a reactive O₂ gas 122 may be used, and additional Ar gas 126 may be used to regulate purge and pressure. The flow rates of the O₂ gas 122 and the additional Ar gas 126 are controlled by gas MFCs 132 and 136, respectively. The O₂ gas 122 and the additional Ar gas 126 are respectively injected through conduit portions 143 and 145 into the process chamber 101. In this case, valves 143a and 145a respectively allow the conduit portions 143 and 145 to open or close off.

As described above, in the conventional CVD system, each of the process chamber units 100 includes the process chamber 101 and its attached liquid or gas sources 102, 104, 106, 108, 122, 124, and 126 and source suppliers. Thus, the sources 102, 104, 106, 108, 122, 124, and 126, the conduit portions 141, 143, 145, 147, 149, and 151, and the controllers 112, 114, 116, 118, 132, 134, and 136 make up about 40 to 50% of the total cost of the entire system.

Also, since the sources 102, 104, 106, 108, 122, 124, and 126 and the conduits 141, 143, 145, 147, 149, and 151 should be exchanged with new ones periodically, the total cost is further increased. In addition, to exhaust the reactive sources 102, 104, 106, and 108 through the additional purge conduit portion 147 for each wafer in order to stabilize them is quite costly.

### SUMMARY OF THE DISCLOSURE

The present invention may provide a duplex chemical vapor deposition (CVD) system, which cuts down the cost of production and component exchanges.

The present invention may also provide a pulsed processing method using a duplex CVD system.

According to an aspect of the present invention, there may be provided a duplex CVD system, which includes first and second process chambers; one or more reactive sources; and reactive source suppliers for supplying the reactive sources to the first and second process chambers, respectively. The reactive source suppliers may include a first conduit portion connected to the respective reactive sources, a second conduit portion having one terminal connected to the first conduit portion and the other terminal connected to the first process chamber, and a third conduit portion having one terminal connected to the first conduit portion and the other terminal connected to the second process chamber.

Each of the reactive source suppliers may include a first valve connected to the second conduit portion and for controlling the flows of the reactive sources into the second conduit portion; and a second valve connected to the third conduit portion and for controlling the flows of the reactive sources into the third conduit portion. Further, each of the reactive source suppliers may include a third valve connected to the first conduit portion and for controlling the flows of the reactive sources into the first conduit portion.

According to another aspect of the present invention, there may be provided a pulsed processing method using the duplex CVD system according to the first aspect of the present invention. The method includes performing a first process only in the first process chamber for a first duration of time by opening the second conduit portion of the reactive source suppliers and closing off the third conduit portion of the reactive source suppliers; and performing a second process only in the second process chamber for a second duration of time by closing off the second conduit portion and opening the third conduit portion, wherein a cycle comprised of the first process and the second process may be repeated several times.

While the first process is being performed, the second process chamber may be maintained at a first pressure by supplying an additional inert gas to the second process chamber using an additional gas supplier. While the second process is being performed, the second process chamber may be maintained at the first pressure.

While the second process is being performed, the first process chamber may be maintained at a second pressure by supplying the additional inert gas to the first process chamber. While the first process is being performed, the first process chamber may be maintained at the second pressure.

### BRIEF DESCRIPTION OF THE DRAWINGS

The above and other features and advantages of the present invention will become more apparent by describing in detail exemplary embodiments thereof with reference to the attached drawings in which:

FIG. 1 is a construction diagram of one process chamber unit of a conventional chemical vapor deposition (CVD) system;

FIG. 2 is a construction diagram of a duplex CVD system according to an exemplary embodiment of the present invention;

FIG. 3 is a flowchart illustrating a pulsed processing method using a duplex CVD system according to an exemplary embodiment of the present invention; and

FIGS. 4, 5, and 6A through 6C are graphs showing experimental results of a pulsed processing method using a duplex CVD system according to an exemplary embodiment of the present invention.

### DETAILED DESCRIPTION OF EXEMPLARY EMBODIMENTS OF THE DISCLOSURE

Embodiments of the present invention will now be described more fully hereinafter with reference to the accompanying drawings, in which the exemplary embodiments of the invention are shown. This invention may, however, be embodied in different forms and should not be construed as limited to the embodiments set forth herein. In the drawings, the thickness of layers and regions are exaggerated for clarity.

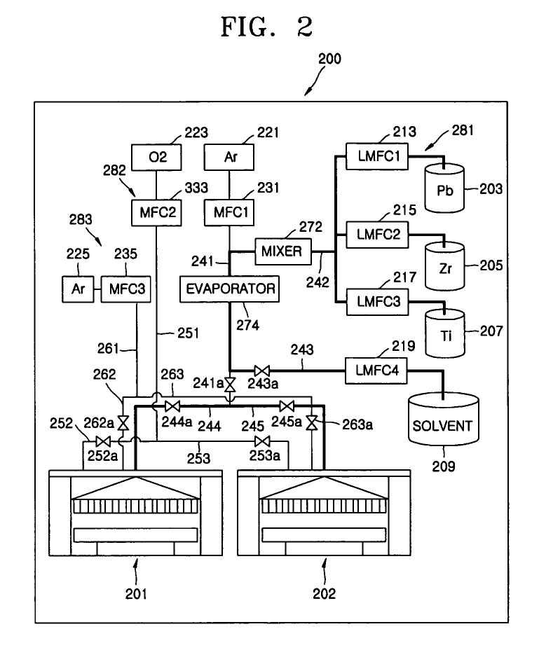

FIG. 2 is a construction diagram of a duplex chemical vapor deposition (CVD) system 200 according to an exemplary embodiment of the present invention.

Referring to FIG. 2, the duplex CVD system 200 according to an embodiment of the present invention may include duplex process chambers 201 and 202, for example, a first process chamber 201 on the left side and a second process chamber 202 on the right side. Also, the duplex CVD system 200 may further include reactive source suppliers 281 and 282, from which reactive sources 203, 205, 207, 209, and 223 for forming a PZT layer may be supplied to process chambers 201 and 202.

The reactive source suppliers 281 and 282 may be comprised of source conduit portions 242, 243, and 251 connected to the reactive sources 203, 205, 207, 209, and 223; chamber conduit portions 244, 245, 252, and 253 connected to the first and second process chambers 201 and 202; and optional intermediate conduit portions 241 and 251 that connect the source conduit portions 242, 243, and 251 and the chamber conduit portions 244, 245, 252, and 253. In this case, the chamber conduit portions 244, 245, 252, and 253 may be classified into, for example, first chamber conduits 244 and 252 connected to the first process chamber 201; and second chamber conduits 245 and 253 connected to the second process chamber 202.

Therefore, unlike in a conventional system, the respective reactive sources 203, 205, 207, 209, and 223 may be supplied to the process chambers 201 and 202 through the reactive source suppliers 281 and 282 that are common to both the process chambers 201 and 202. Hereinafter, the reactive source suppliers 281 and 282 will be described in more detail.

As shown in FIG. 2, a mixer 272 in which the liquid reactive sources 203, 205, and 207 can be mixed with each other may be disposed in the source conduit portion 242 of the first reactive source supplier 281. Also, an evaporator 274 in which the liquid reactive sources 203, 205, and 207 are evaporated may be disposed in the intermediate conduit portion 241. Preferably, a carrier gas, such as Ar gas 221, may be connected to the intermediate conduit portion 241 to facilitate the evaporation and injection of the liquid reactive sources 203, 205, and 207. Meanwhile, the additional source conduit portion 243, which may be connected to a solvent 209, may be connected to the intermediate conduit portion 241 under the evaporator 274 because an evaporation process is not required.

Valves 241a, 243a, 244a, and 245a may be disposed in the conduit portions 241, 243, 244, and 245, respectively, to allow the conduit portions 241, 243, 244, and 245 to open or close off. In particular, by opening one of the valves 244a and 245a connected to the chamber conduit portions 244 and 245 and closing off the other, a pulsed processing method is enabled between the duplex processing chambers 201 and 202 as will be described later.

Liquid mass flow controllers (LMFCs) 213, 215, 217, and 219 may be connected to the liquid reactive sources 203, 205, 207, and 209 and control the flow rates thereof, respectively. Also, a gas mass flow controller (MFC) 231 may control the flow rate of the Ar gas 221 as the carrier gas.

The second reactive source supplier 282 may be used to supply a reactive gas, such as O₂ gas, from the O₂ gas source 223. The O₂ gas source 223 may be connected to the source conduit portion 251, which directly leads without any addition intermediate conduit portion to the chamber conduit portions 252 and 253 that may be connected to the duplex process chambers 201 and 202, respectively. Thus, O₂ gas can be supplied from only one O₂ gas source 223 into the duplex process chambers 201 and 202. Also, a gas MFC 333 may be disposed in the source conduit portion 251 so as to control the flow rate of the O₂ gas supplied from the O₂ gas source 223.

Valves 252a and 253a may be disposed in the chamber conduit portions 252 and 253, respectively, to allow the chamber conduit portions 252 and 253 to open or close off. Thus, by opening one of the valves 252a and 253a and closing off the other, a gas source can be supplied in a pulsed manner from only the O₂ gas source 223 and the reactive source supplier 282 between the duplex process chambers 201 and 202.

Also, as shown in FIG. 2, the duplex CVD system 200 according to an embodiment of the present invention may further include an additional gas supplier 283 for controlling the pressures of the two process chambers 201 and 202. In this case, like the reactive source suppliers 281 and 282, the additional gas supplier 283 also includes a source conduit portion 261 and chamber conduit portions 262 and 263, which connect the source conduit portion 261 and the two process chambers 201 and 202.

Here, in order to control the pressures of the process chambers 201 and 202, other additional Ar gas 225 than the Ar gas 221 for the carrier gas may be used. A gas MFC 235 may be disposed in the source conduit portion 261 to control the flow rate of the additional Ar gas 225. Also, valves 262a and 262b may be disposed in the chamber conduit portions 262 and 263, respectively, to control the flows of the additional Ar gas 225 into the process chambers 201 and 202.

As described above, in the duplex CVD system 200 according to an embodiment of the present invention, the reactive sources 203, 205, 207, 209, and 223, which are common to the two process chambers 201 and 202, may be supplied through the reactive source suppliers 281 and 282, which are common to the two process chambers 201 and 202. Thus, in comparison with a conventional CVD system in which reactive sources and reactive source suppliers are attached to each process chamber, the duplex CVD system 200 according to the present invention may greatly cut down not only the cost of production of the entire system but also the cost of exchange of the reactive source suppliers 281 and 282.

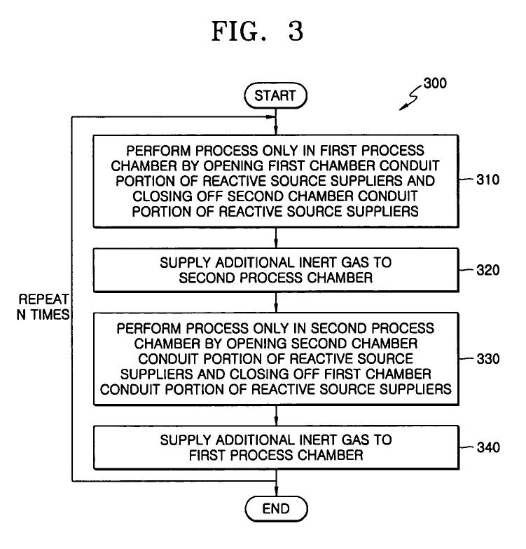

FIG. 3 is a flowchart illustrating a pulsed processing method 300 using a duplex CVD system according to an embodiment of the present invention. Hereinafter, the pulsed processing method according to an embodiment of the present invention will be described with reference to the duplex CVD system shown in FIG. 2.

Referring to FIGS. 2 and 3, according to the pulsed processing method 300 using the duplex CVD system 200, at the outset, the first chamber conduits 244 and 252 of the reactive source suppliers 281 and 282 may be opened, and the second chamber conduits 245 and 253 may be closed off, so that a process may be performed only in the first process chamber 201 (operation 310). In this case, the first chamber conduits 244 and 252 may be opened by opening the valves 244a and 252a. Also, the second chamber conduits 245 and 253 may be closed off by closing off the other valves 245a and 253a.

Thereafter, an additional inert gas, for example, the additional Ar gas 225, may be supplied through the additional gas supplier 283 to the second process chamber 202 (operation 320). In this case, by supplying the additional Ar gas 225, the second process chamber 202 may be maintained at a pressure applied during a process performed in the second process chamber 202, for example, a first pressure. Thus, when a process is subsequently performed in the second process chamber 202, a rapid change in pressure may be evitable to ensure process stability.

In the foregoing operations 310 and 320, while the second process chamber 202 may be being unused and maintained at the first pressure, the process may be performed only in the first process chamber 201 for a predetermined time, for example, a first duration of time.

Thereafter, the second chamber conduits 245 and 253 of the reactive source suppliers 281 and 282 may be opened and the first chamber conduits 244 and 252 may be closed off, so that a process may be performed only in the second process chamber 202 (operation 330). In this case, the first chamber conduits 244 and 252 may be closed off by closing off the valves 244a and 252a. Also, the second chamber conduits 245 and 253 may be opened by opening the other valves 245a and 253a.

Thereafter, an additional inert gas, for example, the additional Ar gas 225, may be supplied through the additional gas supplier 283 to the first process chamber 201 (operation 340). In this case, by supplying the additional Ar gas 225, the first process chamber 201 may be maintained at a pressure applied during operation 310, for example, a second pressure.

In the foregoing operations 330 and 340, while the first process chamber 201 may be being unused and maintained at the second pressure, the process may be performed only in the second process chamber 202 for a predetermined time, for example, a second duration of time. In this case, the first duration of time may be equivalent to the second duration of time.

A cycle comprised of the foregoing four operations 310, 320, 330, and 340 may be repeated n times, thus the pulsed process is performed between the duplex process chambers 201 and 202. The pulse processing method 300 may have a lot of advantages, which will be described later with reference to experimental results. In addition, the alternation of the process between the duplex process chambers 201 and 202 may be advantageous to the economization of the reactive sources 203, 205, 207, 209, and 223.

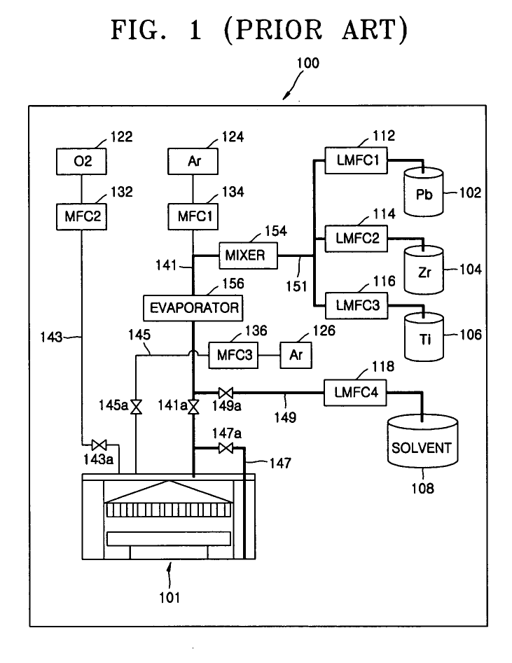

When a pulsed process is performed using one process chamber unit (100 of FIG. 1) of the conventional CVD system, reactive sources may be purged and exhausted for each wafer to achieve process stability. However, according to the pulsed processing method 300 using the duplex CVD system of the present invention, since a process is continuously alternated between the two process chambers 201 and 202, only an initial one-time purge process may be required.

Moreover, in comparison with a pulsed processing method using a conventional CVD system in which a process is repetitively performed and stopped in one process chamber, the pulsed processing method 300 using the duplex CVD system 200 may improve throughput by alternating a process between the two process chambers 201 and 202.

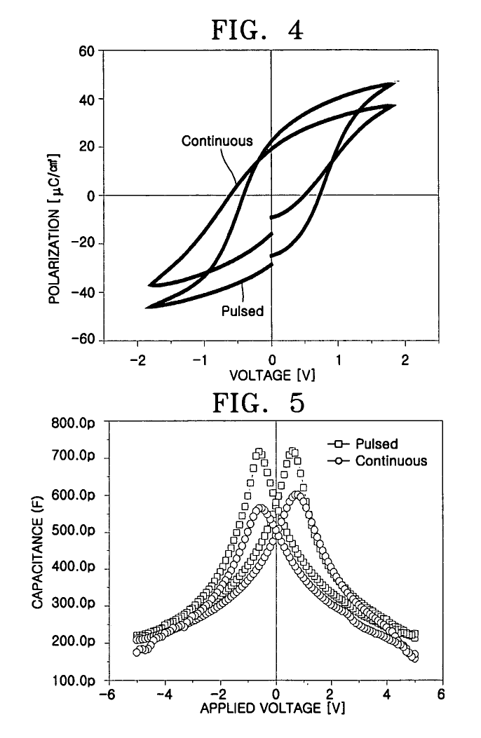

FIGS. 4, 5, and 6A through 6C are graphs showing experimental results of a pulsed processing method using a duplex CVD system according to the present invention.

FIG. 4 is a graph of a polarization value relative to voltage after a PZT layer was formed. Referring to FIG. 4, it can be observed that remnant polarization was higher when a pulsed process is performed (denoted as “Pulsed”), as compared with when a process was continuously performed without a stop (denoted as “Continuous”).

More specifically, it can be seen that the remnant polarization was improved by about 20% or higher using the pulsed process. As the remnant polarization is higher, the sensing reliability of a ferroelectric RAM (FRAM) becomes higher.

FIG. 5 is a graph of capacitance relative to applied voltage. Referring to FIG. 5, it can be observed that capacitance was higher when a pulsed process was performed (denoted as “-□-Pulsed”), as compared with when a process was continuously performed without a stop (denoted as “-o-Continuous”). More specifically, it can be seen that the capacitance was elevated by about 125% using the pulsed process. A rise in the capacitance leads to an increase in the memory capability of an FRAM.

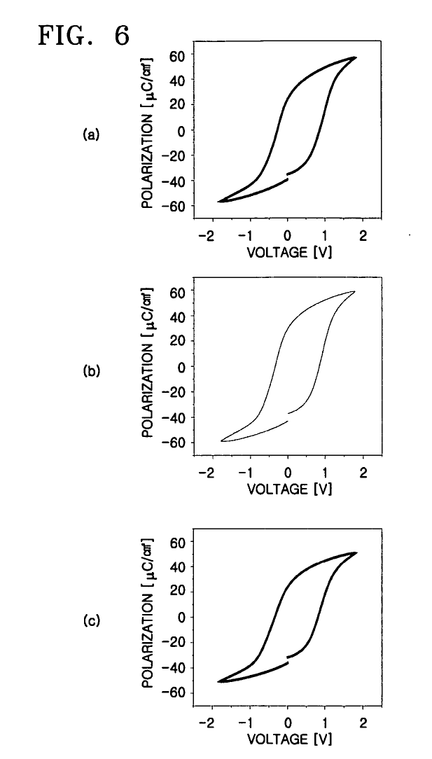

FIGS. 6A through 6C are graphs of voltage relative to process time and stop time in pulsed processes, respectively. In the respective pulsed processes corresponding to FIGS. 6A through 6C, the process time was equal to the stop time. However, on the basis of the pulsed process of FIG. 6A, each of the process time and stop time was increased by about 10 and 20 seconds during the pulsed processes of FIGS. 6B and 6C, respectively.

Referring to FIGS. 6A through 6C, it can be seen that although the process time and stop time were changed, a polarization value made little difference. In other words, a margin for process time taken to perform a process in each process chamber is relatively sufficient according to the pulsed processing method (300 of FIG. 3) using the duplex CVD system (200 of FIG. 2).

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A duplex chemical vapor deposition system comprising:
first and second process chambers;
one or more reactive sources; and
reactive source suppliers for supplying the reactive sources to the first and second process chambers, respectively, the reactive source suppliers comprising a first conduit portion connected to the respective reactive sources, a second conduit portion having one terminal connected to the first conduit portion and the other terminal connected to the first process chamber, and a third conduit portion having one terminal connected to the first conduit portion and the other terminal connected to the second process chamber.

2. The system according to claim 1, wherein each of the reactive source suppliers comprise:
a first valve connected to the second conduit portion and for controlling the flows of the reactive sources into the second conduit portion; and
a second valve connected to the third conduit portion and for controlling the flows of the reactive sources into the third conduit portion.

3. The system according to claim 1, wherein each of the reactive source suppliers comprises a third valve connected to the first conduit portion and for controlling the flows of the reactive sources into the first conduit portion.

4. The system according to claim 1, wherein one or more of the reactive sources are liquid reactive sources.

5. The system according to claim 4, wherein liquid mass flow controllers are disposed at one terminal of the first conduit portion and connected to the liquid reactive sources, respectively.

6. The system according to claim 5, wherein an evaporator for evaporating the liquid reactive sources is disposed in the first conduit portion and connected to the liquid reactive sources.

7. The system according to claim 6, further comprising one or more carrier gases for carrying the liquid reactive sources.

8. The system according to claim 7, wherein the carrier gases include a first gas connected to one terminal of the fourth conduit portion, and the other terminal of the fourth conduit portion is connected to the first conduit portion between the evaporator and the liquid mass flow controllers.

9. The system according to claim 8, wherein the first gas is Ar gas.

10. The system according to claim 8, wherein the fourth conduit includes a gas mass flow controller for controlling the flow of the first gas.

11. The system according to claim 1, wherein one or more of the reactive sources are gas reactive sources.

12. The system according to claim 11, wherein gas mass flow controllers for controlling the flows of the gas reactive sources are disposed in the first conduit.

13. A pulsed processing method using the duplex chemical vapor deposition system according to claim 1, the method comprising:
performing a first process only in the first process chamber for a first duration of time by opening the second conduit portion of the reactive source suppliers and closing off the third conduit portion of the reactive source suppliers; and
performing a second process only in the second process chamber for a second duration of time by closing off the second conduit portion and opening the third conduit portion,
wherein a cycle comprised of the first process and the second process is repeated several times.

14. The method according to claim 13, wherein the first duration of time is equivalent to the second duration of time.

15. The method according to claim 13, wherein while the first process is being performed, the second process chamber is maintained at a first pressure by supplying an additional inert gas to the second process chamber using an additional gas supplier.

16. The method according to claim 15, wherein while the second process is being performed, the second process chamber is maintained at the first pressure.

17. The method according to claim 15, wherein while the second process is being performed, the first process chamber is maintained at a second pressure by supplying the additional inert gas to the first process chamber.

18. The method according to claim 17, wherein while the first process is being performed, the first process chamber is maintained at the second pressure.

19. The method according to claim 15, wherein the additional inert gas is Ar gas.
